(19) United States
(12) Patent Application Publication
(10) Pub. No.: US 2026/0223317 A1
(43) Pub. Date: Jul. 30, 2026

(54) MODULE CAGE HAVING AIR DUCT ASSEMBLY

(71) Applicant: HEWLETT PACKARD ENTERPRISE DEVELOPMENT LP, Spring, TX (US)

(72) Inventors: Foo Luen Wong, Singapore (SG); Tatt Hoong Chow, Singapore (SG); Jia Li Julia Chua, Singapore (SG)

(21) Appl. No.: 19/037,899

(22) Filed: Jan. 27, 2025

(51) Int. Cl. H05K 7/20; H05K 7/14

(52) U.S. Cl. CPC H05K 7/20145; H05K 7/1424; H05K 7/20909

(57) ABSTRACT

An information processing system includes a chassis having a front panel, a rear panel, and a pair of side panels. A module cage is received in and supported by the chassis. The module cage comprises a housing having a first bay and a second bay, each configured to removably receive a pluggable module. The module cage further comprises a duct assembly disposed in the housing and configured to define first and second airflow passages from outside of the module cage to the first and second bays, respectively. The duct assembly is passively actuatable using an actuatable flap from a first state to a second state in response to installation of a pluggable module in the second bay. In the first state, the duct assembly communicably connects the first and second airflow passages, while in the second state, the duct assembly separates the first and second airflow passages from one another.

Information processing systems, (e.g., computers) generate heat during operation and, if the heat is not dissipated or cooling is not provided, damage can occur to various components within the system. One way to provide cooling to a system is through the use of airflow through the system. The air may be generated by fans included within the system. By flowing air over the various components of the system, the individual components are cooled.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system including a module cage having an air duct assembly.

FIG. 2 is a top plan cutaway view of a module cage having an air duct assembly.

FIG. 3 is the module cage of FIG. 2 in a state of one pluggable module installed.

FIG. 4 is the module cage of FIG. 2 in a state of one pluggable module installed and a second pluggable module in the process of being installed.

FIG. 5 is the module cage of FIG. 4 with the second pluggable module fully installed.

FIG. 6 is a rear perspective view of a module cage having an air duct assembly with one pluggable module installed.

FIG. 7 is a detail view of the adjustable flap of FIG. 6.

FIG. 8 is a top view of the module cage of FIG. 6.

FIG. 9 is a side perspective view of the module cage of FIG. 6.

FIG. 10 is a front perspective view of the module cage of FIG. 6.

FIG. 11 is a side perspective view of a module cage having an air duct assembly with two pluggable modules installed.

FIG. 12 is a top perspective view of the module cage of FIG. 11.

FIG. 13 is a front perspective view of the module cage of FIG. 11.

FIG. 14 is a top view of the module cage of FIG. 11.

FIG. 15 is an example method for installing modules in an information processing system having a module cage having an air duct assembly.

### DETAILED DESCRIPTION

In some systems, certain components may be housed within sub-compartments within the larger system chassis, with these sub-compartments often being referred to as cages. For example, power supply units (PSUs) are often housed within a PSU cage at a rear of the system. A portion of the air flowing through the system chassis will enter the cages and cool the components installed therein.

Often, a system may be somewhat modular in nature; that is, components may be selectively added or removed according to the needs and design of the system. Thus, a cage which is capable of receiving multiple components will not necessarily be fully populated with the maximum number of components. For example, a PSU cage may have multiple bays capable of receiving multiple PSUs, but in some cases, only a subset of the PSUs may be installed at a given time.

Sometimes, a cage may have a shared or common air intake through which cooling airflows enter the cage, and each component installed int eh cage may receive a portion of the airflows passing through this shared air intake. In such systems, it can sometimes be the case that some components installed int eh cage will receive more cooling air than others, resulting in unequal cooling of the components. For example, a component which is installed in a bay which is closer to the shared air intake may receive more air than a component which is installed in a bay further from the shared air intake. Thus, fan speeds may need to be set high enough to ensure that the component installed in the farthest bay receives adequate cooling, which can increase electricity consumption and noise generation.

In other systems, a cage may have separate air intakes for each bay to ensure that each bay receives equal amounts of air and thus equal cooling. However, a drawback of these systems is that, when less than all of the bays are populated by components, the airflows which would have flowed through the unpopulated bays goes unused. Thus, some of the electricity consumed to generate this airflow may be wasted. Moreover, the individual air intakes of each bay may be relatively small (compared to a shared air intake for an entire cage), which may limit the amount of air which can be delivered to any given bay at a given fan speed.

Thus, cages, with shared intake may suffer from unequal cooling when all bays are fully populated, whereas cages with separate air intakes may suffer from limited and wasted airflows when less than all bays are fully populated.

To address these and other issues, examples disclosed herein comprise a cage having two bays and a passively actuatable air duct assembly configured to direct airflows through the bays. The air duct assembly is actuatable between at least two states, including a second state in which the air duct assembly defines separate airflow passages to the two bays and a first state in which the airflow passage to one bay is communicably coupled with the airflow passage to another bay. The air duct assembly is configured to be passively actuatable between these states based on whether a particular one of the bays is populated or unpopulated. If the bay is populated (e.g., both bays have a pluggable module installed), the air duct assembly automatically enters the second state, whereas if the particular bay lacks a pluggable module installed therein, the air duct assembly automatically enters the first state. Thus, when both bays are populated, the air duct assembly in the second state provides equal distribution of air to all the bays. On the other hand, when less than all the bays are populated, the air duct assembly in the first state directs the airflows of the unpopulated bay into the populated bay, thus increasing the amount of air passing therethrough. In other words, in the first state, airflows from the unpopulated bay may be delivered to the populated bay, thus increasing the amount of air passing therethrough. This can allow for improved cooling and/or decreased fan speeds and therefore reduced power consumption and noise generation.

In some examples, the module cage is a PSU cage for use in an information processing system, such as a server. The PSU cage may comprise a housing formed by a number of walls/panels and two PSU bays defined inside the housing, with each bay sized to receive one PSU. In some examples, the air duct assembly comprises a first chamber which forms at least part of the first airflow passage to the first PSU bay and a second chamber which forms at least part of the second airflow passage to the second PSU bay. The first chamber has a first inlet opening communicably connected to the interior of the system chassis, a passthrough opening communicably connected to the second PSU bay, and a first outlet opening communicably connected to the first PSU bay. The second chamber has a second inlet opening connected to the interior of the chassis and a second outlet opening communicably connected to the second PSU bay. As such, air can flow through the first chamber to the first PSU bay and through the second chamber to the second PSU slot. Air can also flow from the second passage to the first airflow passage via the passthrough opening, if the passthrough opening is open. The passthrough opening is selectively opened or closed depending on the state of the air duct assembly, as will be described below.

The duct assembly further comprises an actuatable flap disposed adjacent to the first and second outlet openings of the first and second chamber. The actuatable flap is configured to selectively open or close the passthrough opening based on whether a PSU is inserted into the second PSU bay. Said differently, the actuatable flap changes the airflow through the system by blocking and opening the passthrough opening. When the second PSU bay is unpopulated, the actuatable flap does not block the passthrough opening, and therefore the second airflow passage is communicably connected to the first airflow passage via the passthrough opening. This corresponds to the first state of the air duct assembly. When the second PSU bay is populated, the actuatable flap blocks the passthrough opening, thereby separating the two airflow passages. This corresponds to the second state of the air duct assembly.

The actuatable flap may include a biasing element, such as a spring, to bias the actuatable flap in an open position. Thus, if a first PUS is inserted into a first PSU bay but a second PSU bay is left unpopulated, the actuatable flap automatically stays in the open position (i.e., the first state of the air duct assembly). When a second PSU is inserted into the second PSU bay, the second PSU collides with the flap and the force against the actuatable flap by the PSU is sufficient to overcome the biasing force and move the flap into the closed position (i.e., the air duct assembly transitions to the second state). More particularly, the actuatable flap may include a cam arm that is configured to be contacted by the second PSU as the second PSU is inserted into the second PSU slot. The cam translates the motion of the second PSU into rotation of the flap to close the flap. Thus, the flap is passively actuated between the closed state and the opened state. When the second PSU is removed from the second PSU slot, the second PSU breaks contact with the cam, allowing the spring to return the actuatable flap to the open position.

When the flap is in the open position (first state), i.e., when only one PSU is installed in the cage, the first chamber and the second chamber both supply airflow to the first PSU bay. More particularly, a first airflow flows into the first chamber through the first inlet opening and from there into the first PSU bay via the first outlet opening. At the same time, a second airflow flows into the second chamber via the second inlet opening, and then this second airflow flows out of the second chamber and into the first PSU bay via the passthrough opening and the first outlet opening. Thus, the first and second airflows, which originate at the first and second inlet openings, respectively, and pass through the first and second chambers, respectively, ultimately both end up passing into the first PSU bay. However, when the flap is in the closed position (second state), i.e., when a second PSU is installed in the cage, the first chamber supplies airflow to the first PSU and the second chamber supplies airflow to the second PSU.

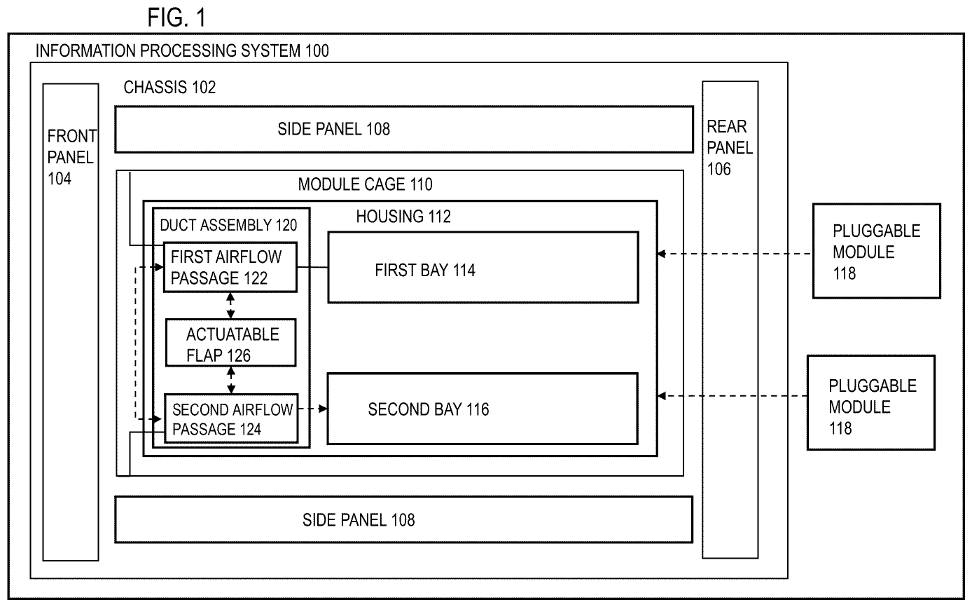

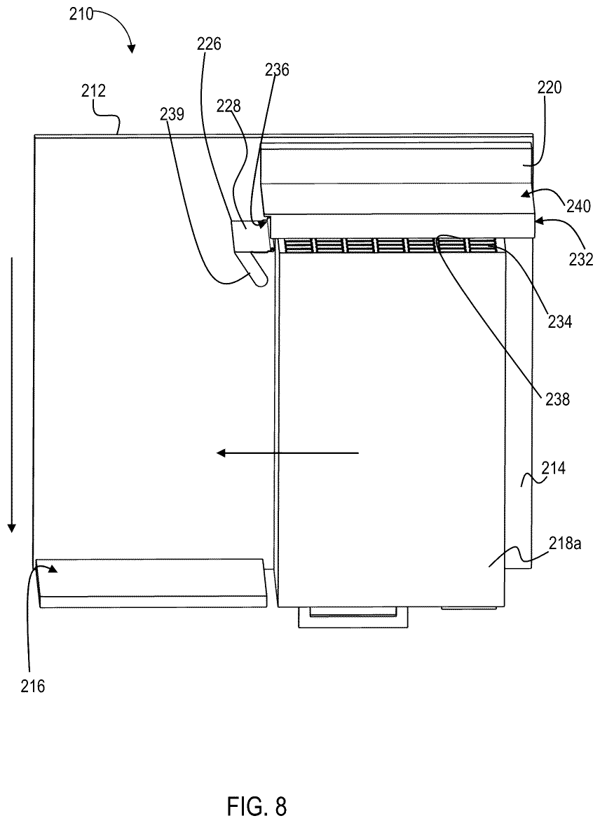

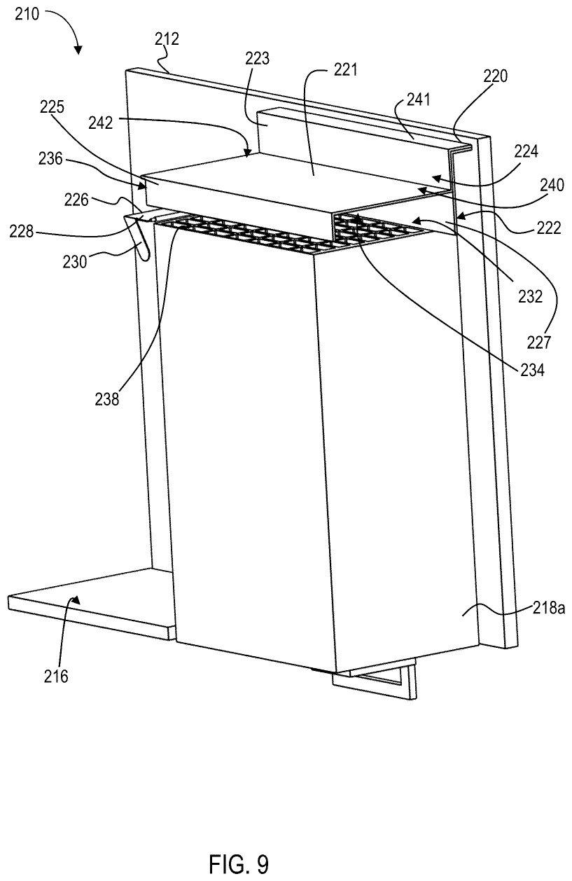

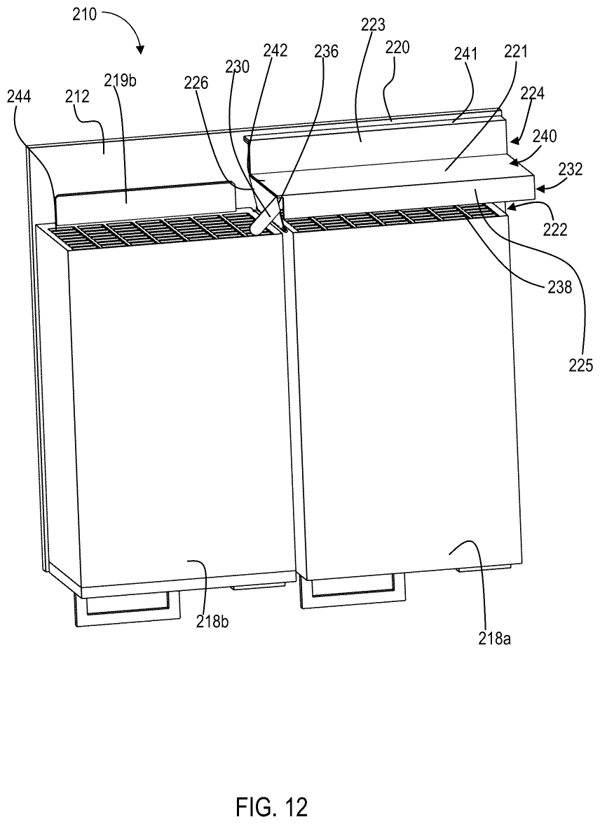

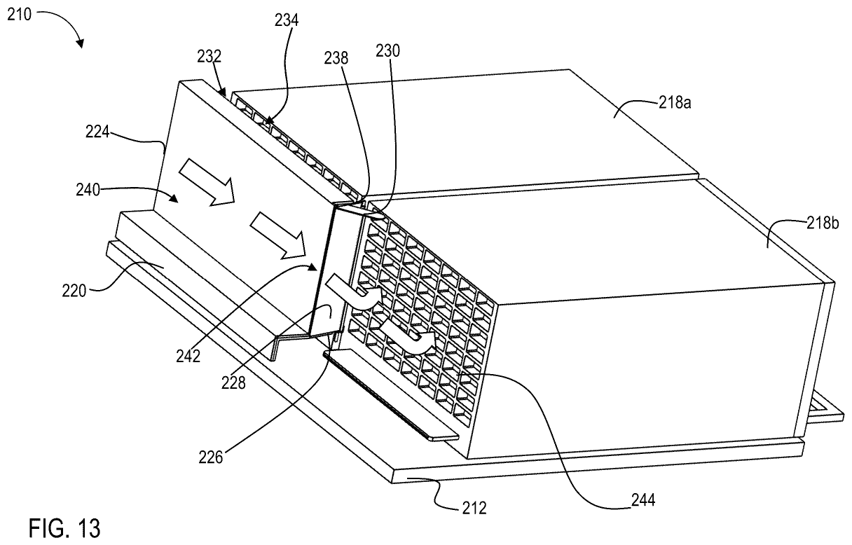

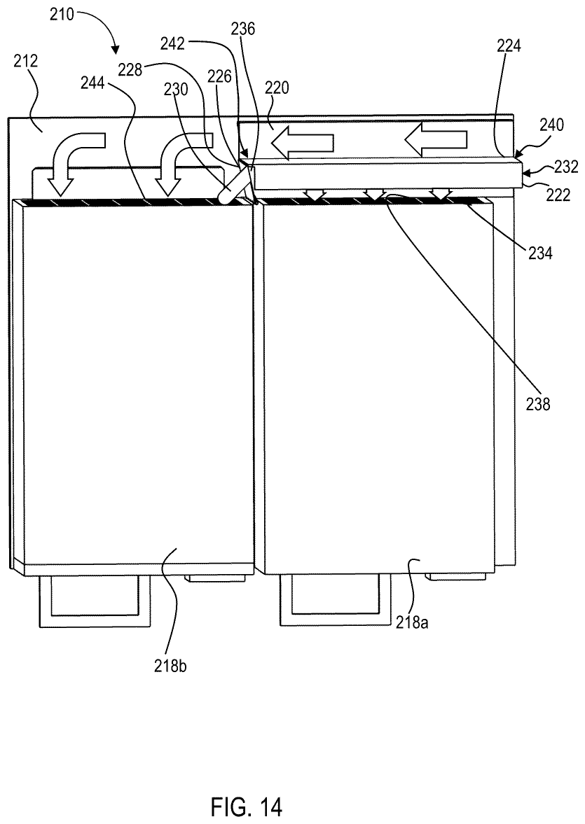

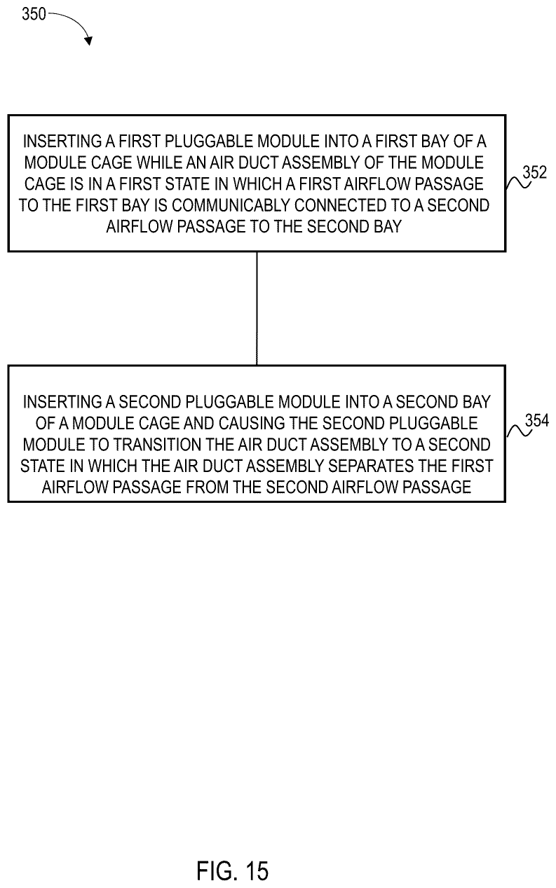

These and other examples will be described in greater detail below in relation to FIGS. 1-15.

FIG. 1 illustrates an example information processing system 100. FIG. 1 is schematic in nature, and it should be understood that FIG. 1 is not intended to illustrate specific shapes, dimensions, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Furthermore, connections which may be intermittent or conditional (e.g., occurring in some states but not in others) are indicated by dashed-line arrows.

Information processing system includes a chassis 102 which physically supports, and in some cases encloses or houses, the other components of the system 100. The chassis 102 may include a front panel 104 and a rear panel 106, as well as side panels 108 disposed between and connecting the front panel 104 and the rear panel 106. Side panels 108 may be substantially parallel to one another and substantially perpendicular to each of the front panel 104 and the rear panel 106. Chassis 102 may further include other structural members (not illustrated) such as a base, a cover, etc.

Information processing system 100 may further include a module cage 110. Module cage 110 may be coupled to the chassis 102. As described previously, module cage 110 may be configured to receive a pluggable module, such as pluggable modules 118, within bays 114, 116 defined therein. More particularly, module cage 110 may include a housing 112 defining a volume which may be further divided into a first bay 114 and a second bay 116, with each bay 114, 116 configured to receive a pluggable module such as pluggable module 118.

Housing 112 may further include a duct assembly 120 disposed therein, with duct assembly 120 being disposed adjacent to the first bay 114 and the second bay 116. The duct assembly 120 may define a first airflow passage 122 and a second airflow passage 124. Both first airflow passage 122 and second airflow passage 124 may be defined from outside of the module cage 110 to the first bay 114 and the second bay 116, respectively. That is, first airflow passage 122 and second airflow passage 124 may be communicatively coupled with a portion of the chassis 102 external to the module cage 110 such that air may flow from the chassis 102 through the module cage 110 and housing 112 via the first airflow passage 122 and the second airflow passage 124. More particularly, airflow may pass through the first airflow passage 122 to the first bay 114 and through the second airflow passage 124 to the second bay 116.

The duct assembly 120 may further include an actuatable flap 126, which may be used to passively actuate duct assembly 120. More particularly, actuatable flap 126 may be used to move the duct assembly 120 from a first state to a second state, with the second state occurring responsive to a pluggable module 118 being installed in the second bay 116. In the first state, the actuatable flap 126 may be in an open position such that the first airflow passage 122 and the second airflow passage 124 are communicably coupled with one another, such that airflow through the first airflow passage 122 and the second airflow passage 124 may be exchanged therethrough, as well as directed to the first bay 114, which may have a pluggable module 118 received therein.

In the second state, the actuatable flap 126 may be in a closed position such that the duct assembly 120 separates the first airflow passage 122 and the second airflow passage 124 from one another. Said another way, in the second state, the first airflow passage 122 and the second airflow passage 124 may no longer be communicably coupled with one another as they were in the first state. Thus, airflow through the first airflow passage 122 may be separated from airflow through the second airflow passage 124.

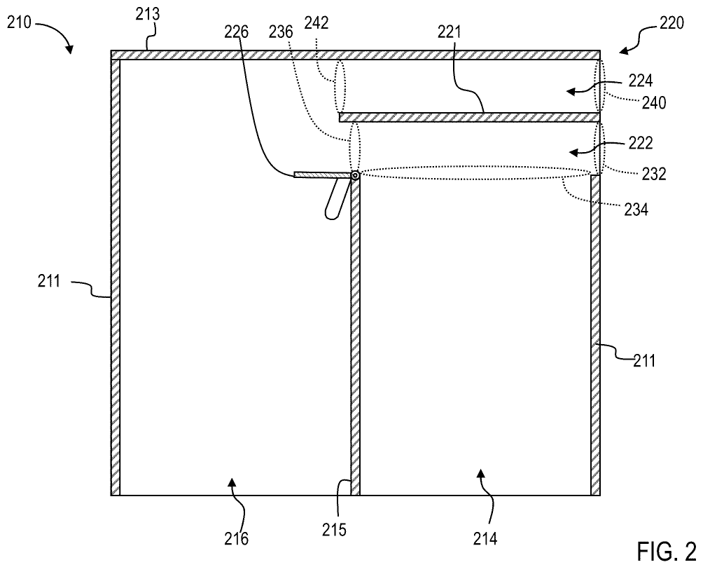

Turning now to FIGS. 2-14, an example of a module cage 210 that could be used in an information processing system such as system 100 is shown. Module cage 210 may be one implementation example of module cage 110 shown in and described with respect to FIG. 1 and may be used in a system such as system 100, described with respect to FIG. 1. Module cage 210 thus comprises components which correspond to (i.e., are implementation examples of) components of the module cage 110, and the correspondence between such components is indicated herein by the components having reference numbers with the same last two digits, such as 126 and 226. Aspects of the module cage 110 and its components described above may also be applicable to the module cage 210 and its corresponding components, but the module cage 110 and its components are not limited to the module cage 210 and its components, which are just one example of how the module cage 110 may be implemented. In some instances, aspects of the module cage 110 already described above, which are also applicable to the module cage 210, are not described below to avoid duplicative description.

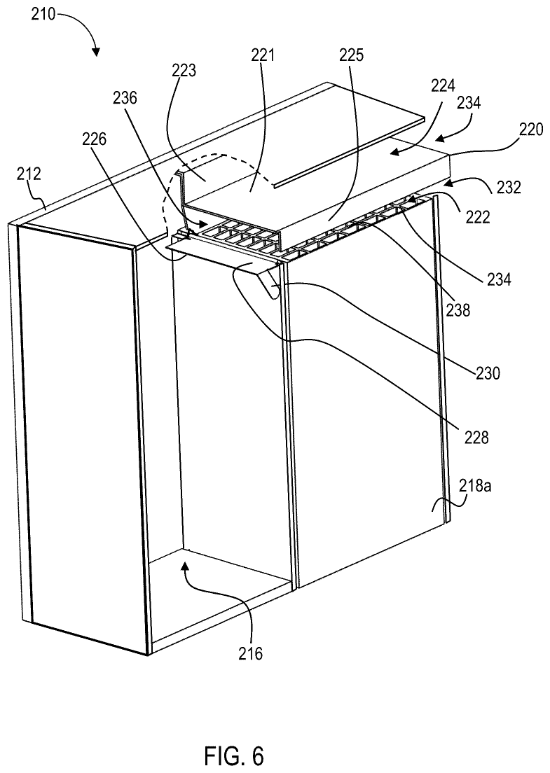

Module cage 210 includes a housing 212 in which a first bay 214 and a second bay 216 are defined. As shown in FIGS. 2-5, housing 212 may include a pair of side walls 211 disposed parallel to one another and connected by a top wall 213. The side walls 211 and top wall 213 may define a volume in which first bay 214 and second bay 216 are defined. More particularly, housing 212 may further include a divider wall 215 disposed substantially parallel to the side walls 211 to divide the volume of the housing 212 into the first bay 214 and the second bay 216. Said differently, the divider wall 216 may serve as one side boundary of the first bay 214 and the second bay 216, with side walls 211 forming the other side boundaries thereof. It should be noted that in FIGS. 6-14, the side walls 211, top wall 213, and divider wall 215 of the housing 212 are omitted to simplify the drawings; however, the side walls 211, top wall 213, and divider wall 215 are understood to be part of the housing 212 even if not labeled as such.

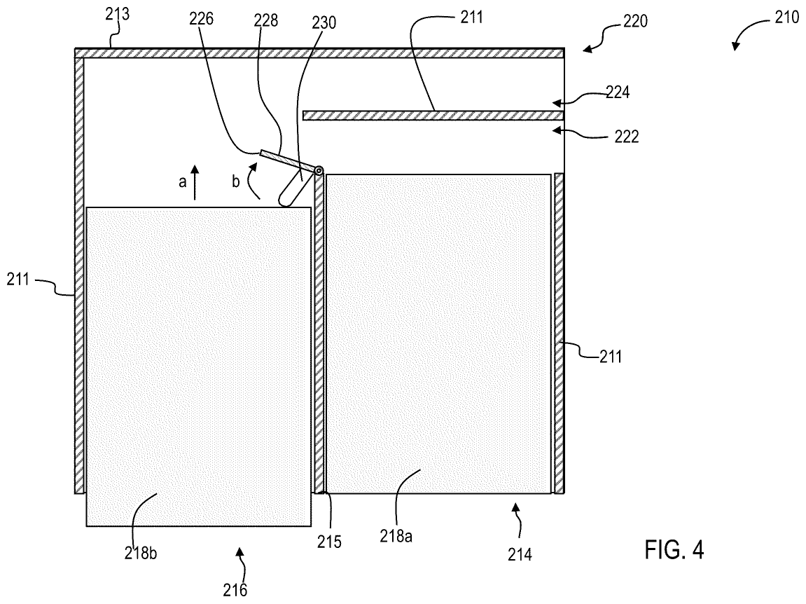

As shown in FIGS. 2 and 6-10, the first bay 214 may receive a first pluggable module 218a, while the second bay 216 may remain empty. However, the second bay 216 may receive a second pluggable module 218b, as shown in FIGS. 4-5 and 11-14, Each of the first pluggable module 218a and the second pluggable module 218b may be removably received within their respective bays 214 and 216; that is, each pluggable module 218a, 218b may be inserted and/or removed from the housing 212 of module cage 210.

A duct assembly 220 may be disposed in the housing 212. The duct assembly may include a first airflow passage 222 and a second airflow passage 224. The duct assembly 220 may be configured such that the first airflow passage 222 is a first chamber and the second airflow passage 224 is a second chamber. As shown in FIGS. 2-7 and 9-12, the duct assembly 220 may include a center wall 221 dividing an internal volume of the duct assembly 220 into the first airflow passage 222 and the second airflow passage. Said differently, an upper boundary of the first airflow passage 222 may be a bottom face of the center wall 221, while a lower boundary of the second airflow passage 224 may be a top face of the center wall 221.

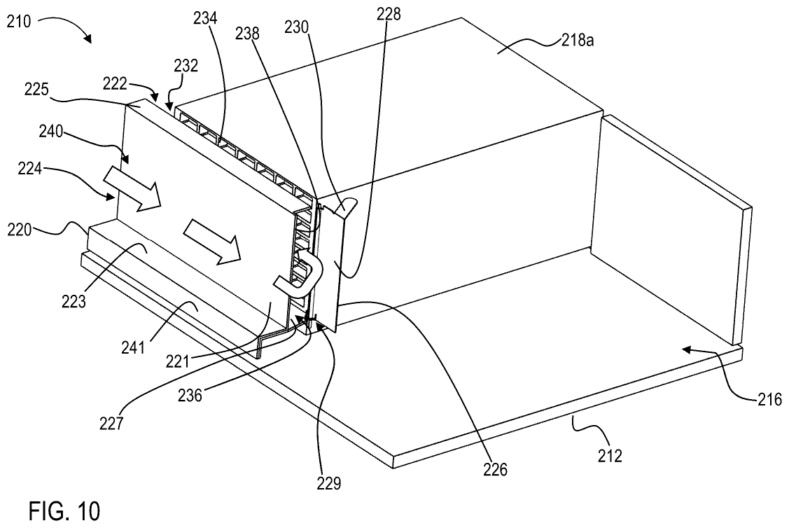

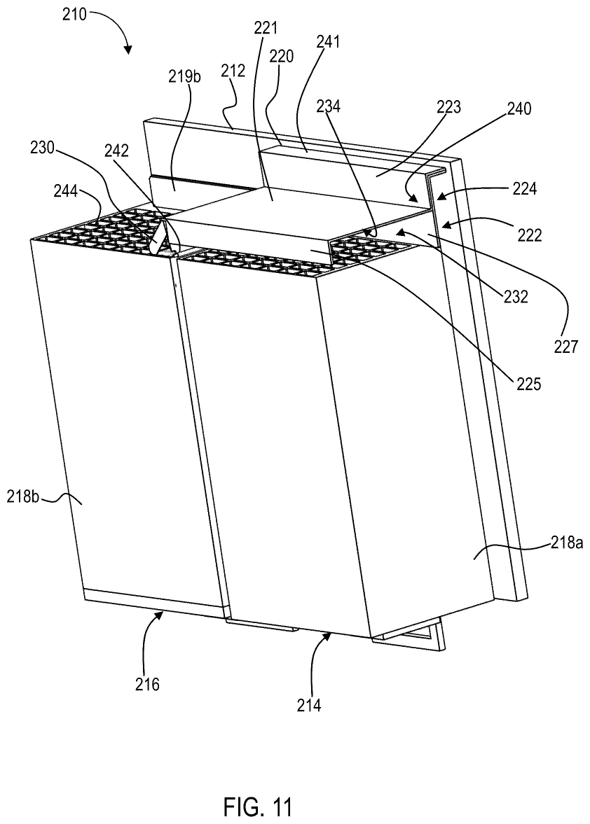

As shown particularly in FIGS. 6 and 9-12, the duct assembly 220 may further comprise a rear wall 223 extending perpendicular from the center wall 221 away from the first bay 214. The rear wall 223 may be a second boundary wall for the second airflow passage 224. An upper bracket 241 may extend perpendicularly away from the rear wall 241. As shown in FIG. 10, the upper bracket 241 may allow rear wall 223 to be spaced apart from housing 212. This spacing apart may allow first pluggable module 218a to engage with an electrical connector disposed in the housing. As shown in FIGS. 11-14, second pluggable module 218b may have an edge connector 219b. First pluggable module 218a may have a corresponding edge connector. The edge connector of pluggable module 218a may extend into the space created between the housing 212 and the rear wall 223, allowing the first pluggable module to engage with an electrical connector when the air duct assembly 220 is installed.

In some examples, the air duct assembly 220 may include additional walls. For example, a lower wall may be disposed along at least part of a length of the first airflow passage 222, parallel to the center wall 221. In some examples, an upper wall may extend from the rear wall 223 parallel to the center wall 221 along at least part of a length of the second airflow passage 224. In other examples, a cover placed on the module cage 210 may act as a wall of the second airflow passage 224.

The first airflow passage 222 includes a first inlet opening 232, which communicably couples the first airflow passage 222 to a volume outside the housing 212. In some examples, the volume outside the housing 212 may be a volume formed by a chassis, such as chassis 102, in which module cage 210 may be located. Air may flow into the first airflow passage 222 at the first inlet opening 232.

A first outlet opening 234 may communicably couple the first airflow passage 222 to the first bay 214. In some examples, the first outlet opening 234 may be disposed substantially along a length of the first airflow passage 222, as shown in, e.g., FIGS. 2, 5, and 8-11. In other examples, such as when at least a part of the first airflow passage 222 is bounded by a lower wall, the first outlet opening 234 may be formed within said lower wall. The outlet opening 234 may allow air that flows through the first airflow passage 222 to flow into the first bay 214 and over a first pluggable module 218awhen the first pluggable module 218a is in an installed state. In some examples, the pluggable module 218a may include a first module grate 238 to allow air to flow over internal components of the pluggable module 218a.

Similarly, the second airflow passage 224 includes a second inlet opening 240 to communicably couple the second airflow passage 224 to a volume outside the housing 212. As with the first inlet opening 232, the second inlet opening 240 may communicably couple the second airflow passage 224 with a volume formed in a chassis holding the module cage 210, such that air flows into the second airflow passage 224 by via the second inlet opening 240.

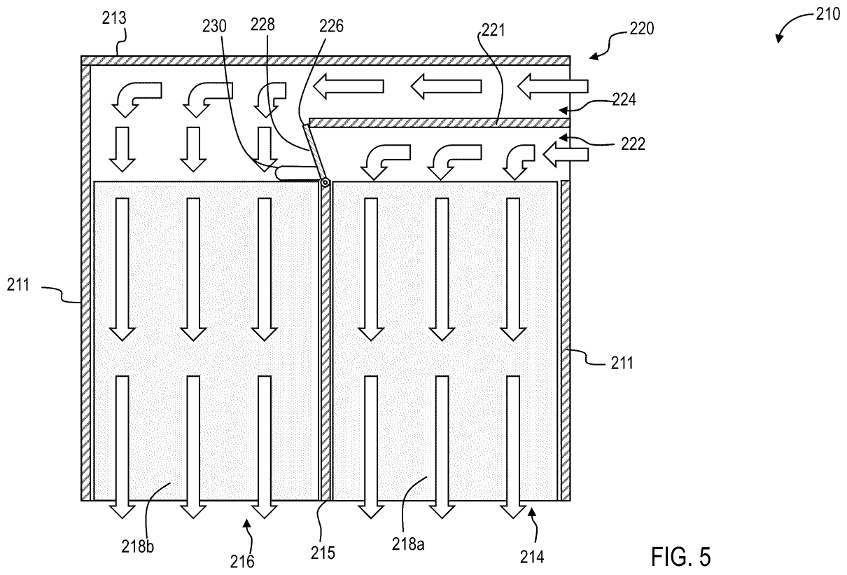

A second outlet opening 242 may communicably couple the second airflow passage 224 to the second bay 216. In some examples, the second outlet opening 242 may be disposed opposite the second inlet opening 240 such that air flows along the length of second airflow passage 224 from the second inlet opening 240 to the second outlet opening 242. The second outlet opening 240 may extend along a width of the second airflow passage 224 as shown in, e.g., FIGS. 2, 9, and 12-14. Thus, when a second module 218b is installed in module cage 210, as shown in FIGS. 5 and 11-14, the second outlet opening 242 may be located adjacent to the second module 218b such that air flowing through the second airflow passage 224 is directed to the second module 218b received in the second bay 216. More particularly, the second module 218b may include a second module grate 244 that allows air flowing through the second outlet opening 242 to flow over interior components of the second module 218b.

A passthrough opening 236 may be disposed opposite the first inlet opening 232. The passthrough opening 236 may be configured such that it communicably connects the first airflow passage 222 and the second airflow passage 224. Said differently, the passthrough opening 236 may be disposed to allow airflow between the first airflow passage 222 and the second airflow passage 224.

An actuatable flap 226 may be disposed at the passthrough opening 236. The actuatable flap 226 may be configured to move between a first state and a second state. More particularly, when the actuatable flap 226 is in the first state, the actuatable flap 226 may be in an open position, shown in FIGS. 2-3, 6, and 8-10. In the open position, the passthrough opening 236 is open; that is, the first airflow passage 222 and the second airflow passage 224 are communicably coupled to one another. Conversely, when the actuatable flap 226 is in the second state, the actuatable flap 226 may be in a closed position, shown in FIGS. 5 and 11-14. In the closed position, the actuatable flap 226 may block the passthrough opening 236 such that the first airflow passage 222 and the second airflow passage 236 are no longer communicably coupled with one another.

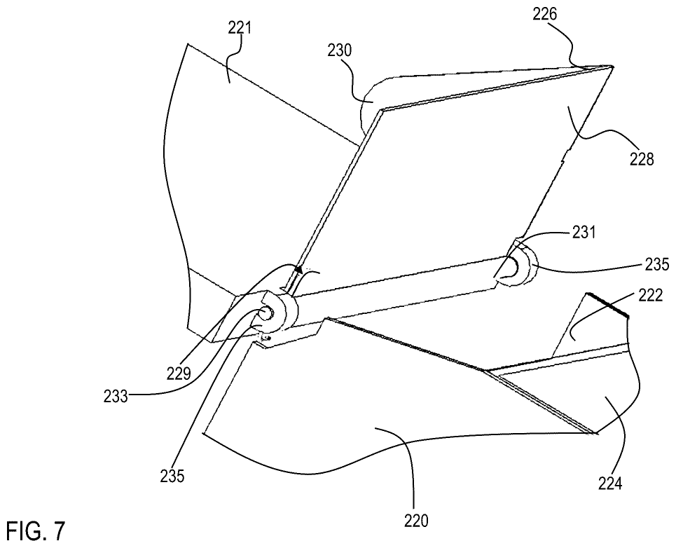

As particularly shown in FIG. 7, the actuatable flap 226 may further comprise a baffle 228 configured to selectively block the passthrough opening 236. A cam arm 230 may be coupled to the baffle 228 at a lower portion thereof. The cam arm 230 may be configured to engage with a second pluggable module 218b when the second pluggable module 218b is installed within the module cage 210.

The actuatable flap 226 may further include a biasing element 229 contained within a housing portion 231 adjacent to the baffle 228. The biasing element 229 may be held within the housing portion 231 by a pin 233 received within the housing portion 231 such that the biasing element 229 is maintained in its position within the housing portion 231. In some examples, the biasing element 229 may be a spring, although examples are not so limited and other elements may be used for biasing. The biasing element 229 may be configured to bias the baffle 228, and thus the actuatable flap 226, in the open position; that is, the actuatable flap 226 may be biased by the biasing element 229 to be in the first state, shown in FIGS. 2 and 4-6.

As shown in FIG. 7, the baffle 228 may extend outwardly from the housing portion 231 such that baffle 228 is rotatable about the housing portion 231. Thus, the baffle 228 may move between the first state and the second state via rotation. More particularly, the baffle 228 may be rotated from the first state, where the passthrough opening 236 is unblocked, to the second state, where the baffle 228 blocks the passthrough opening 236.

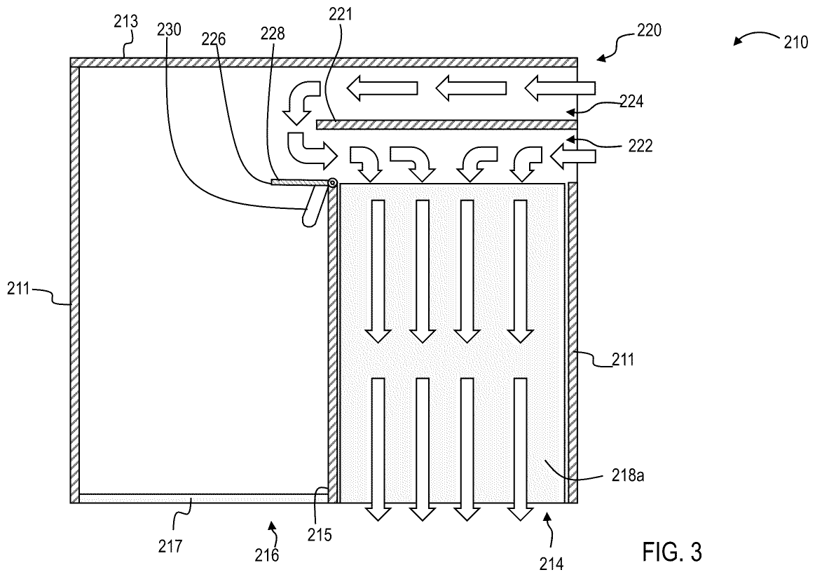

As shown in FIGS. 3, 5, and 8-10, when a first module 218a is installed in the module cage 210 and a second bay 216 does not have a module installed therein, actuatable flap 226 is in an open position, or a first state, allowing the passthrough opening 236 to communicably couple the first airflow passage 222 and the second airflow passage 224. In the open position of the actuatable flap 226, the cam arm 230 extends into the second bay 216 and the baffle 228 extends parallel to the first airflow passage 222 and parallel to the first module grate 238. Thus, when the actuatable flap 226 is in the open position, air flows into first airflow passage 222 through the first inlet opening 232, as shown in FIG. 3. The air then flows over the first module 218a after exiting the first airflow passage 222 at the first outlet opening 234.

Similarly, when the actuatable flap 226 is in the first state or the open position, air flows into the second airflow passage 224 through the second inlet opening 240, as shown in FIG. 3. Upon reaching the second outlet opening 242, the air flows towards the second bay 216. Because the passthrough opening 236 is not blocked by baffle 228, some of the air that exits the second airflow passage 224 re-enters the first airflow passage 222 at the passthrough opening 236, as shown in FIG. 3. This re-entered air is then able exit the first airflow passage 222 at the first outlet opening 224 and flow over the first module 218a. In this manner, first module 218a may receive airflow through both the first airflow passage 222 and the second airflow passage 224. As a result, cooling of the first module 218a may be maximized. In addition, because a second source of airflow into the first module 218a is present when the actuatable flap 226 is in the first state (namely, air flowing through the second airflow passage 224 and into the first airflow passage 222 via the passthrough opening 236), fans, which may be utilized for cooling, may be able to be run at a lower speed.

When a second module 218b is installed in the module cage 210, as shown in FIGS. 4-5 and 11-14, the actuatable flap 226 may be moved from the first state to the second state, in which the baffle 228 blocks the passthrough opening 236. The actuatable flap 226 may be moved into the second state by the second module 218b as the second module 218b is installed within the second bay 216. More particularly, as shown in FIG. 4, the second module 218b is moved along the second bay 216, an upper portion of the second module 218b, such as the second module grate 244, may contact the cam arm 230 of the actuatable flap 226. As the second module 218b continues to move along the second bay 216, the second module 218b exerts a force on the cam arm 230. This force on the cam arm 230 from the second module 218b is sufficient to overcome the bias from the biasing element 229, allowing the actuatable flap 226 to be rotated about the housing portion 231 until the baffle 228 covers the passthrough opening 236. Said differently, when the second pluggable module 218b contacts the cam arm 230, the continued motion of the second pluggable module 218b is converted to motion of the actuatable flap 226 by engagement of the cam arm 230 and the second pluggable module 218b.

When the module cage 210 has both a first pluggable module 218a and a second pluggable module 218b installed therein, as shown in FIGS. 7-10, the duct assembly 220 is in the second state as a result of the movement of the actuatable flap 226 described previously. Thus, in the second state, the first pluggable module 218a, located in the first bay 214, receives air through the first airflow passage 222, while the second pluggable module 218b, located in the second bay 216, receives air through the second airflow passage 224 More particularly, air enters the first airflow passage 222 at the first inlet opening 232, which is connected to a volume outside the module cage 210. The air then exits the first airflow passage 222 at the first outlet opening 234, where it the is able to flow to the first pluggable module 218a due to the communicable coupling of the first bay 214, and thus the first pluggable module 218a, with the first outlet opening 234.

Similarly, air enters the second airflow passage 224 at the second inlet opening 240, which is connected to a volume outside the module cage 210. The air then exits the second airflow passage 224 at the second outlet opening 242, where it flows to the second pluggable module 218b due to the communicable coupling of the second bay 216, and thus the second pluggable module 218b, with the second outlet opening 242. However, unlike when the air duct assembly 220 is in the first state, i.e., when the actuatable flap 226 is in the open position, air exiting the second airflow passage 224 at the second outlet opening 242 is unable to re-enter the first airflow passage 222 at the passthrough opening 236. As a result, the airflows for both the first pluggable module 218a and the second pluggable module 218b are limited to the air flowing through the first airflow passage 222 and the second airflow passage 224, respectively.

Due to the modular nature of the module cage 210, second module 218b may be selectively inserted into and removed from the second bay 216 based on system needs and considerations. When the second module 218b is removed from the second bay 216, the second module 218b is moved back along a length of the second bay 216. As the second module 218b is moved out of the second bay 216, the contact between the second module 218b and the cam arm 230 of the actuatable flap 226 is removed. As a result, the force exerted on the cam arm 226 by the second module 218b, which was able to overcome the bias from the biasing element 229, is removed. Thus, the actuatable flap 226 returns to the open position, or the first state, in which the baffle 228 is biased by the biasing element 229 to not cover the passthrough opening 226. In this manner, the actuatable flap 226 is selectively actuatable between the first, open, state and the second, closed, state, with the second state occurring in response to installation of a second pluggable module 218b into the module cage 210.

FIG. 11 is an example method 350 for configuring an information processing system. At 352, method 350 includes inserting a first pluggable module into a first bay of a module cage. The module cage may be supported by a chassis of the information processing system, as described with respect to FIG. 1. The module cage may include an air duct assembly, such as the air duct assembly 220 described with respect to FIGS. 2-10. The air duct assembly may include a first airflow passage and a second airflow passage that are configured to direct air from outside of the module cage to the first bay and the second bay, respectively.

The module cage may further include a second bay, which may be unpopulated when the first pluggable module is inserted into the first bay of the module cage at 352. Thus, the air duct assembly may be in a first state, in which the air duct assembly communicably couples a first airflow passage of the air duct assembly with a second airflow passage of the air duct assembly. More particularly, as described with respect to FIGS. 2-10, the air duct assembly may include an actuatable flap, which may be in an open position when the first pluggable module is inserted into the first bay at 352.

At 354, method 350 includes inserting a second pluggable module into the second bay of the module cage. The first pluggable module, installed at 352, may remain in its installed position, such that the module cage has two pluggable modules installed therein, as shown in FIGS. 7-10. Inserting the second pluggable module at 354 may further comprise causing the air duct assembly to transition from the first state to a second state, with the second state corresponding to a state in which the air duct assembly separates the first airflow passage from the second airflow passage. More particularly, as discussed previously with respect to FIGS. 7-10, the second pluggable module may cause the actuatable flap to transition to the second state by contacting the actuatable flap and moving the actuatable flap to a closed position. As described with respect to FIGS. 7-10, the actuatable flap may include a cam arm which is contacted by the second pluggable module when the second pluggable module is inserted at 354. This contact between the cam arm and the second pluggable module may cause rotation of the actuatable flap in response to continued motion of the second pluggable module along the second bay as the second pluggable module moves towards its final installed position.

Method 350 further comprises removing the second pluggable module from the second bay of the module cage. Removing the second pluggable module from the second bay includes removing contact from the actuatable flap and the second module. As described previously with respect to FIGS. 2-6, the actuatable flap may include a biasing element that biases the actuatable flap into an open position. Thus, when the second pluggable module is removed from the module cage and contact between the actuatable flap and the second pluggable module is broken, the second pluggable module no longer exerts a force on the actuatable flap to overcome the bias from the biasing element. As a result, the actuatable flap moves back to the open state, returning the air duct assembly to the first state in which the first airflow passage and the second airflow passage are communicably coupled with one another.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a chassis having a front panel, a rear panel, and a pair of side panels;
a module cage received in and supported by the chassis, the module cage comprising:
a housing;
a first bay and a second bay in the housing, each bay configured to removably receive a pluggable module; and
a duct assembly disposed in the housing and configured to define first and second airflow passages from outside of the module cage to the first and second bays, respectively,
wherein the duct assembly is passively actuatable using an actuatable flap from a first state to a second state in response to installation of a pluggable module in the second bay, and
wherein in the first state, the duct assembly communicably connects the first and second airflow passages together, and in the second state the duct assembly separates the first and second airflow passages from one another.

2. The information processing system of claim 1, wherein:
the duct assembly comprises a first chamber and a second chamber;
the actuatable flap is disposed at a passthrough opening communicably connecting the first chamber and the second chamber and configured to move between an open position and a closed position;
the first airflow passage comprises the first chamber and the second airflow passage comprises the second chamber;
in the first state the actuatable flap is in an open position and does not block the passthrough opening; and
in the second state, the actuatable flap is in the closed position and blocks the passthrough opening.

3. The information processing system of claim 2, wherein:
the first chamber of the duct assembly further comprises a first inlet opening communicably coupling the first chamber to a volume outside the housing and a first outlet opening communicably coupling the first chamber to the first bay; and
the second chamber of the duct assembly further comprises a second inlet opening communicably coupling the first chamber to the volume outside the housing and a second outlet opening communicably coupling the first chamber to the first bay.

4. The system of claim 1, wherein the actuatable flap further comprises:
a baffle configured to selectively block the passthrough opening of the duct assembly;
a cam arm coupled to the baffle; and
a biasing element to bias the actuatable flap to an open position.

5. The system of claim 4, wherein the biasing element is a spring.

6. The system of claim 1, wherein:
the actuatable flap is configured to move between an open position and a closed position to selectively actuate the duct assembly between the first state and the second state;
the actuatable flap is in the open position and the duct assembly is in the first state when a first pluggable module is installed in the first bay; and
the actuatable flap is moved to the closed position and the duct assembly is in the second state when a second pluggable module is installed in the second bay.

7. The system of claim 6, wherein the actuatable flap is configured to, on condition of the second pluggable module being installed in the second bay, return to the open position in response to the second pluggable module being removed from the module cage.

8. A pluggable module cage for an information processing system, comprising:
a module cage housing configured to be supported by a chassis of the information processing system and comprising a first bay and a second bay configured to removably receive a first pluggable module and a second pluggable module, respectively; and
a duct assembly disposed along a front portion of the module cage housing, the duct assembly further comprising:
a first chamber having a first inlet opening and a first outlet opening;
a second chamber having a second inlet opening and a second outlet opening;
a passthrough opening communicably connecting the first chamber to the second chamber; and
an actuatable flap disposed adjacent to the passthrough opening and configured to move between an open position in which the actuatable flap does not cover the passthrough opening and a closed position in which the actuatable flap covers the passthrough opening, the actuatable flap further comprising:
a baffle configured to selectively cover the passthrough opening;
a biasing element configured to bias the baffle in the open position; and
a cam arm coupled to the baffle and configured to be engaged by the second pluggable module to convert motion of the second pluggable module to motion of the actuatable flap.

9. The pluggable module cage of claim 8, wherein:
the first inlet opening is communicably connected to an air inlet of the chassis; and
the second inlet opening is communicably connected to the air inlet of the chassis.

10. The pluggable module cage of claim 8, wherein:
the first outlet opening is communicably coupled to the first bay; and
the second outlet opening is communicably coupled to the second bay.

11. The pluggable module cage of claim 8, wherein the biasing element is a spring.

12. The pluggable module cage of claim 8, wherein the second pluggable module exerts a force on the cam arm to overcome the bias from the biasing element when the second pluggable module engages the cam arm.

13. The pluggable module cage of claim 8, wherein the baffle blocks the passthrough opening when the actuatable flap is in the closed position.

14. The air ducting system of claim 8, wherein:
the actuatable flap is in the open position when the first pluggable module is installed in the module cage; and
the actuatable flap moves to the closed position when the second pluggable module is installed in the module cage.

15. The air ducting system of claim 8, wherein, in a state of the actuatable flap being in the open position, air flows through the first chamber to the first bay and through the second chamber to the first bay by the passthrough opening.

16. The air ducting system of claim 8, wherein, in a state of the actuatable flap being in the closed position, air flows through the first chamber to the first bay and air flows through the second chamber to the second bay.

17. A method of configuring an information processing system, comprising:
inserting a first pluggable module into a first bay of a module cage supported by a chassis of the information processing system while a second bay of the module cage is unpopulated and an air duct assembly is in a first state, wherein in the first state, the air duct assembly communicably connects a first airflow passage of the air duct assembly with a second airflow passage of the air duct assembly, and the first and second airflow passages are configured to direct air from outside of the module cage to the first bay and the second bay, respectively; and
inserting a second pluggable module into the second bay of the module cage and causing the second pluggable module to transition the air duct assembly from the first state to a second state in which the air duct assembly separates the first airflow passage from the second airflow passage.

18. The method of claim 17, wherein inserting a second pluggable module into the second bay further comprises contacting an actuatable flap of the air duct assembly, wherein contact between the second pluggable module and the actuatable flap causes the actuatable flap to move to a closed position.

19. The method of claim 18, wherein the second pluggable module contacts the actuatable flap at a cam arm such that movement of the second pluggable module against the cam arm causes rotation of the actuatable flap.

20. The method of claim 18, further comprising removing the second pluggable module from the second bay of the module cage, wherein removing the second pluggable module further comprises removing contact between the second module and the actuatable flap such that the actuatable flap moves to an open position and the air duct assembly returns to the first state.
